(19) United States
(12) Patent Application Publication
(10) Pub. No.: US 2026/0287437 A1
(43) Pub. Date: Sep. 24, 2026

(54) ELECTROMAGNETIC WAVE SENSOR

(71) Applicant: TDK Corporation, Tokyo (JP)

(72) Inventors: Shinji HARA, Tokyo (JP); Susumu AOKI, Tokyo (JP); Naoki OHTA, Tokyo (JP); Takahiro NAKAGAWA, Tokyo (JP)

(73) Assignee: TDK Corporation, Tokyo (JP)

(21) Appl. No.: 19/573,274

(22) Filed: Mar. 20, 2026

(30) Foreign Application Priority Data
Mar. 24, 2025 (JP) 2025-048848

(51) Int. Cl. G01J 5/24; G01J 5/20; H10F 30/10; H10F 39/90; H10F 77/00; H10F 77/20

(52) U.S. Cl. CPC G01J 5/24; H10F 30/10; H10F 39/90; H10F 77/20; H10F 77/93; G01J 2005/202

(57) ABSTRACT

An electromagnetic wave sensor comprises a first wiring that extends in a first direction, two second wirings that are separated by an interspace in the first direction and that extend in a second direction that is different from the first direction, and a bolometer. The bolometer includes electrodes. The first wiring is positioned on a side where electromagnetic waves to be measured are incident, relative to the bolometer. The position of the bolometer in a third direction that is orthogonal to the first direction and the second direction is between the position of the first wiring in the third direction and the position of the second wirings in the third direction. When viewed from the third direction, at least a part of the electrodes overlaps the interspace, and the bolometer overlaps the two second wirings.

### FIELD

This application claims the benefit of Japanese Priority Patent Application No. 2025-048848 filed on Mar. 24, 2025, the entire contents of which are incorporated herein by reference.

The present disclosure relates to an electromagnetic wave sensor.

### BACKGROUND

JP 2024-073823 A describes an electromagnetic wave sensor that comprises a thermistor element, a pair of arm parts, first wirings that extend in a first direction, and second wirings that extend in a second direction that is different from the first direction. The thermistor element includes an insulator layer, a thermistor film, and electrodes. The first wirings are positioned on a side where electromagnetic waves to be measured are incident, relative to the thermistor element, and the second wirings are positioned on the side of the thermistor element that is opposite the side on which the first wirings are positioned. The second wirings reflect the electromagnetic waves transmitted through the thermistor element to cause the electromagnetic waves to be absorbed by the thermistor element. The thermistor element is entirely covered by one second wiring when viewed from a third direction that is orthogonal to the first and second directions.

### SUMMARY

The electromagnetic wave sensor of the present disclosure comprises a first wiring that extends in a first direction, two second wirings that are separated by an interspace in the first direction and that extend in a second direction that is different from the first direction, and a bolometer. The bolometer includes electrodes. The first wiring is positioned on a side where electromagnetic waves to be measured are incident, relative to the bolometer, and position of the bolometer in a third direction that is orthogonal to the first direction and the second direction is between position of the first wiring in the third direction and position of the second wirings in the third direction. When viewed from the third direction, at least a part of the electrodes overlaps the interspace. When viewed from the third direction, the bolometer overlaps the two second wirings.

### BRIEF DESCRIPTION OF THE DRAWINGS

The accompanying drawings are included to provide a further understanding of the disclosure and are incorporated in and constitute a part of this specification. The drawings illustrate example embodiments and together with the specification explain the principles of the technology.

FIG. 1 is a schematic side view of the electromagnetic wave sensor of the first embodiment of the present disclosure;

FIGS. 2A and 2B are partial schematic plan views of the electromagnetic wave sensor shown in FIG. 1;

FIGS. 3A to 3D are partial schematic cross-sectional views of the electromagnetic wave sensor shown in FIG. 1;

FIG. 4A is a partial schematic plan view of the electromagnetic wave sensor of Comparative Example 1;

FIGS. 4B and 4C are partial schematic cross-sectional views of the electromagnetic wave sensor of Comparative Example 1;

FIG. 5 is a partial schematic plan view of the electromagnetic wave sensor of Modification b 1;

FIG. 6 is a schematic cross-sectional view of the electromagnetic wave sensor of Modification 2;

FIG. 7 is a schematic cross-sectional view of the electromagnetic wave sensor of Comparative Example 2;

FIG. 8A is a partial schematic plan view of the electromagnetic wave sensor of the second embodiment of the present disclosure; and

FIG. 8B is a partial schematic cross-sectional view of the electromagnetic wave sensor of the second embodiment of the present disclosure.

### DETAILED DESCRIPTION

Because the electrodes of a thermistor element (electromagnetic wave detector) have low transmittance of electromagnetic waves, electromagnetic waves are unlikely to reach the area of the second wiring that underlies the electrodes when viewed from the third direction, and as a result, the second wiring cannot efficiently reflect electromagnetic waves.

It is desirable to provide an electromagnetic wave sensor that can efficiently reflect electromagnetic waves transmitted through an electromagnetic wave detector and thus increase the absorption efficiency of electromagnetic waves absorbed by the electromagnetic wave detector.

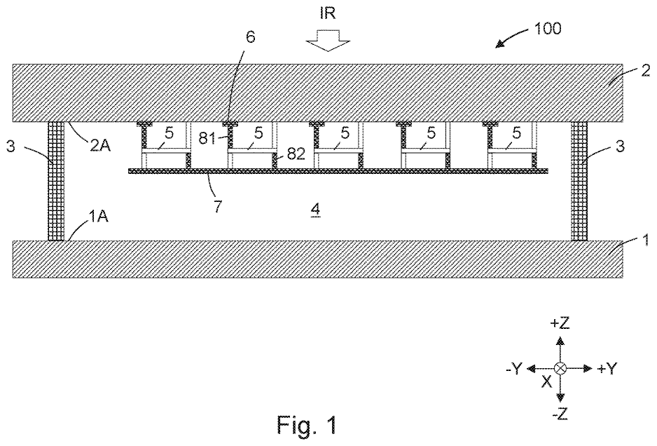

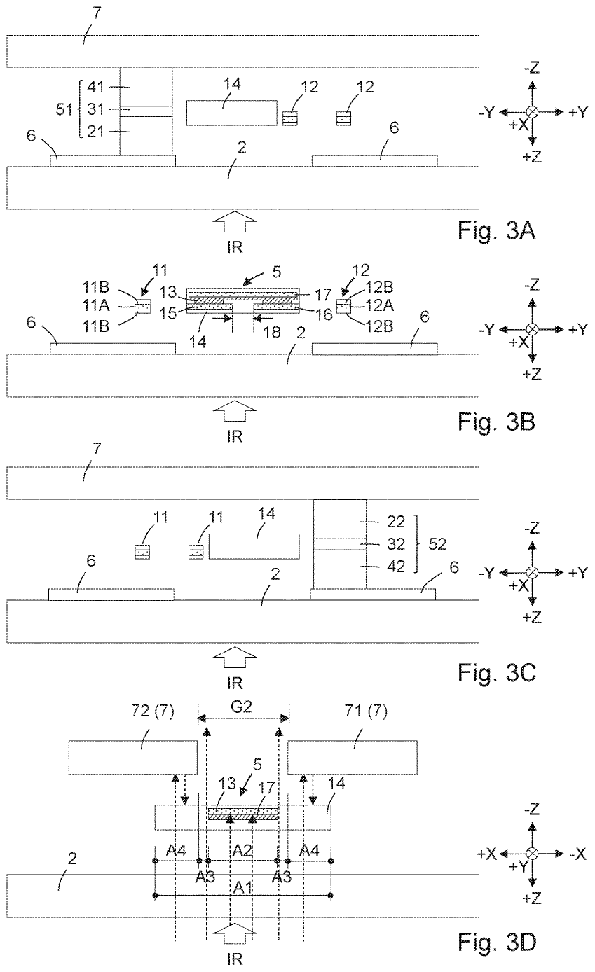

Embodiments of electromagnetic wave sensor 100 of the present disclosure are next described with reference to the drawings. The drawings are schematic diagrams illustrating the present disclosure, and in some cases, the shapes and dimensions of the elements in the drawings may not necessarily coincide. In the following description and drawings, the X-direction (also referred to as the “first direction”) and the Y-direction (also referred to as the “second direction”) are parallel to principal surface 1A of first substrate 1 and principal surface 2A of second substrate 2. Principal surface 1A is the surface of first substrate 1 that faces second substrate 2. Principal surface 2A is the surface of second substrate 2 that faces first substrate 1. In the present embodiment, the X-direction and the Y-direction are orthogonal to each other, and the Y-direction can be any direction different from the X-direction. The Z-direction (also referred to as the “third direction”) is orthogonal to the X-direction and the Y-direction and is perpendicular to principal surface 1A of first substrate 1 and principal surface 2A of second substrate 2. The Z-direction may also be referred to as the film thickness direction of electromagnetic wave detector 5. As shown in the drawings, the X-direction may be distinguished as the +X-direction and the −X-direction, the Y-direction may be distinguished as the +Y direction and the −Y-direction, and the Z-direction may be distinguished as the +Z-direction and the −Z-direction. The +Z-direction is the direction from first substrate 1 to second substrate 2, and the −Z-direction is the direction from second substrate 2 to first substrate 1. The up-down orientation of the +Z-direction in FIG. 1 is opposite to the orientation of the +Z-direction in FIGS. 3A to 3D, 4B, 4C, 6, 7 and 8B.

The following embodiments are directed to an infrared sensor in which electromagnetic wave detectors (bolometers) are arranged in a two-dimensional array. The infrared sensor mainly detects long-wavelength infrared rays. The wavelength of long-wavelength infrared rays is approximately 8 to 14 μm. Infrared sensors of this type are mainly used as image sensors for infrared cameras. Infrared cameras can be used in night-vision scopes and night-vision goggles in dark places and can also be used as sensor for measuring the temperatures of people and objects. The electromagnetic waves to be detected are not limited to infrared rays and can be, for example, terahertz waves with wavelengths of 100 μm to 1 mm.

### First Embodiment

### Overall Configuration

FIG. 1 is a schematic side view of electromagnetic wave sensor 100 of the present embodiment. In FIG. 1, arm parts 11 and 12 are not shown. In FIG. 1, five electromagnetic wave detectors 5 are arranged in the Y-direction, but as described below, the number of electromagnetic wave detectors 5 is not limited. Electromagnetic wave sensor 100 comprises first substrate 1 and second substrate 2 that are arranged opposite each other, and side walls 3 that both connect and encircle first substrate 1 and second substrate 2 in the circumferential direction. First substrate 1, second substrate 2, and side walls 3 form sealed internal space 4. Internal space 4 is provided with electromagnetic wave detectors 5 that function as the sensing parts of electromagnetic wave sensor 100, first wirings 6 that extend in the X-direction, and second wirings 7 that extend in the Y-direction. Electromagnetic wave detectors 5 absorb incident electromagnetic waves and convert the electromagnetic waves into heat for detection. Electromagnetic wave detectors 5 are bolometers. Because internal space 4 is under negative pressure or in a vacuum, this configuration can prevent or reduce convection of gases in internal space 4 and thus reduce the thermal effect upon electromagnetic wave detectors 5.

First substrate 1 is formed mainly of a silicon substrate. First substrate 1 is equipped with internal wirings (not shown) and electrical circuits such as readout ICs (ROICs) that read the output signals of electromagnetic wave detectors 5. Pads (not shown) are formed on the outer sides of side walls 3 of first substrate 1 for input from and output to the outside. The pads are electrically connected to electrical circuits by internal wiring. Second substrate 2 is also formed mainly of a silicon substrate. Second substrate 2 is the substrate on the side of incidence of electromagnetic waves IR to be detected and supports electromagnetic wave detectors 5. Second substrate 2 transmits electromagnetic waves IR and thus allows the incidence of electromagnetic waves IR to electromagnetic wave detectors 5. First substrate 1 and second substrate 2 may be germanium substrates that transmit electromagnetic waves.

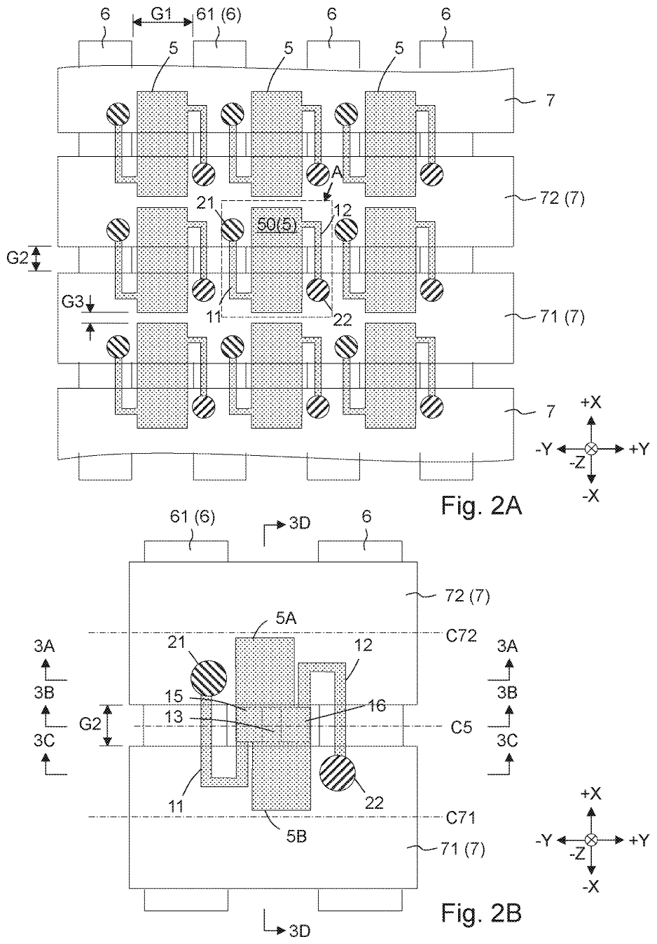

FIG. 2A is a partial plan view of electromagnetic wave sensor 100 viewed from the +Z-direction, and FIG. 2B is an enlarged view of area A in FIG. 2A. The position of electromagnetic wave detectors 5 in the Z-direction is between the position of first wirings 6 in the Z-direction and the position of second wirings 7 in the Z-direction, and for the sake of convenience, electromagnetic wave detectors 5 are shown in FIGS. 2A and 2B. FIG. 2A shows a simplified shape of electromagnetic wave detectors 5. In FIG. 2B, of electromagnetic wave detectors 5, only electromagnetic wave detector 5 in area A is illustrated as electromagnetic wave detector 50. FIG. 3A shows a schematic cross-sectional view taken along line 3A−3A of FIG. 2B, FIG. 3B shows a schematic cross-sectional view taken along line 3B−3B of FIG. 2B, FIG. 3C shows a schematic cross-sectional view taken along line 3C−3C of FIG. 2B, and FIG. 3D shows a schematic cross-sectional view taken along line 3D−3D of FIG. 2B. Electromagnetic wave detectors 5 are arranged to form a two-dimensional grid array. Temperature detection film 13 (see FIGS. 3B and 3D) of each electromagnetic wave detector 5 constitutes one cell or pixel in the array. The number of matrices in the array includes, but is not limited to, for example, 640 rows by 480 columns or 1024 rows by 768 columns.

Electromagnetic wave sensor 100 comprises first wirings 6 that extend in the X-direction with interspaces G1 in the Y-direction between the wirings, and second wirings 7 that extend in the Y-direction with interspaces G2 in the X-direction between the wirings. First wirings 6 and second wirings 7 are supported by second substrate 2. First wirings 6 are provided on second substrate 2, and second wirings 7 are provided at a position apart from second substrate 2 in the −Z-direction. In other words, first wirings 6 are positioned on the side where electromagnetic waves IR to be measured are incident, relative to electromagnetic wave detectors 5, and the position of electromagnetic wave detectors 5 in the Z-direction is between the position of first wirings 6 in the Z-direction and the position of second wirings 7 in the Z-direction. First wirings 6 and second wirings 7 are electrically connected to the ROICs of first substrate 1 by electrical connection members (not shown). First wirings 6 and second wirings 7 can be made of metals such as Al, Cu, Au, Ag, alloys mainly composed of these metals, and conductive nitrides such as TiN, ZrN, WN, and CrN.

### Configuration of Electromagnetic Wave Detector 5

As shown in FIGS. 2A and 2B, each electromagnetic wave detector 5 is connected to first arm part 11 and second arm part 12 that supports electromagnetic wave detector 5. As shown in FIG. 3B, first arm part 11 comprises conductive layer 11A that is electrically connected to first electrode layer 15 (see below), and dielectric layers 11B that cover conductive layer 11A. Second arm part 12 comprises conductive layer 12A that is electrically connected to second electrode layer 16 (see below), and dielectric layers 12B that cover conductive layer 12A. As shown in FIGS. 3B and 3D, each electromagnetic wave detector 5 includes temperature detection film 13 that constitutes a temperature sensing part, electromagnetic wave absorber 14 that constitutes an electromagnetic wave absorption part, and electrode layers (in the present embodiment, first electrode layer 15, second electrode layer 16, and third electrode layer 17). First electrode layer 15, second electrode layer 16, and third electrode layer 17 can be made of, for example, metals such as Al, Cu, Au, and Ag, alloys mainly composed of these metals, and conductive nitrides such as TiN, ZrN, WN, and CrN. When viewed from the Z-direction, first electrode layer 15, second electrode layer 16, and third electrode layer 17 overlap at least one of temperature detection film 13 and electromagnetic wave absorber 14 included in electromagnetic wave detector 5.

Temperature detection film 13 is formed of, for example, a thermistor film, and the thermistor film may include, for example, at least one of vanadium oxide, amorphous silicon, polycrystalline silicon, oxides with spinel-type crystal structures containing manganese, titanium oxide, yttrium-barium-copper oxide, and nanocarbon materials such as graphene or carbon nanotubes. Temperature detection film 13 may be a thermocouple film, a thermopile film, a diode film such as a silicon diode, or a pyroelectric film such as a lead zirconate titanate film. Temperature detection film 13 is provided in the center portion of electromagnetic wave detector 5 in the X-direction and is disposed continuously across substantially the entire width of the center portion in the Y-direction. Electromagnetic wave absorber 14 covers at least a part (all in the present embodiment) of temperature detection film 13 and absorbs electromagnetic waves IR to be measured. Electromagnetic wave absorber 14 can be made of a dielectric such as aluminum nitride, silicon nitride, aluminum oxide, or silicon oxide. Although not shown in the drawings, temperature detection film 13 and electromagnetic wave absorber 14 can also be formed as a single film by using a material with electromagnetic wave absorbing properties such as amorphous silicon. In other words, temperature detection film 13 may also serve as electromagnetic wave absorber 14 (electromagnetic wave absorber 14 may also serve as temperature detection film 13).

First electrode layer 15 is electrically connected to temperature detection film 13 as well as to first wiring 6 via conductive layer 11A of first arm part 11. Second electrode layer 16 is electrically connected to temperature detection film 13 as well as to second wiring 7 via conductive layer 12A of second arm part 12. First electrode layer 15, second electrode layer 16, and third electrode layer 17 are provided in the center portion of each electromagnetic wave detector 5 in the X-direction, and gap 18 is provided between first electrode layer 15 and second electrode layer 16. Third electrode layer 17 is provided on the surface of temperature detection film 13 that is opposite the side on which first electrode layer 15 and second electrode layer 16 are provided. In the present embodiment, first electrode layer 15 and second electrode layer 16 are on the −Z-side of temperature detection film 13, and third electrode layer 17 is on the +Z-side of temperature detection film 13. Alternatively, first electrode layer 15 and second electrode layer 16 may be on the +Z-side of temperature detection film 13, and third electrode layer 17 may be on the −Z-side of temperature detection film 13. Third electrode layer 17 is provided continuously across the center portion of electromagnetic wave detector 5 in the X-direction and across nearly the entire width in the Y-direction of the center portion. When viewed from the Z-direction, third electrode layer 17 overlaps first electrode layer 15 and second electrode layer 16. In the present embodiment, third electrode layer 17 overlaps all of first electrode layer 15 and second electrode layer 16 and further overlaps gap 18 between first electrode layer 15 and second electrode layer 16 when viewed from the Z-direction.

Electromagnetic wave sensor 100 comprises first pillar portions 21 and second pillar portions 22 that are columnar and conductive. First and second pillar portions 21 and 22 extend in a direction that includes at least a component in the Z-direction (in the present embodiment, entirely in the Z-direction). Each first pillar portion 21 is electrically connected to corresponding first arm part 11 and one corresponding first wiring 6, and each second pillar portion 22 is electrically connected to corresponding second arm part 12 and one corresponding second wiring 7. In other words, each individual electromagnetic wave detector 5 is electrically connected to one corresponding first wiring 6 via first pillar portion 21 and to one corresponding second wiring 7 via second pillar portion 22. As a result, DC current flows between each electromagnetic wave detector 5 and first wiring 6 via first pillar portion 21 and flows between electromagnetic wave detector 5 and second wiring 7 via second pillar portion 22. In the present embodiment, DC current flows in the order of (or in the reverse order of) first wiring 6, first pillar portion 21, first arm part 11, electromagnetic wave detector 5, second arm part 12, second pillar portion 22, and second wiring 7. Inside each electromagnetic wave detector 5, DC current flows between first electrode layer 15 and third electrode layer 17, and further, flows between second electrode layer 16 and third electrode layer 17. In other words, DC current flows in the film thickness direction (the Z-direction) of temperature detection film 13. When viewed from the Z-direction, first pillar portion 21 that electrically connects electromagnetic wave detector 50 to first wiring 61 also overlaps second wiring 72, and second pillar portion 22 that electrically connects electromagnetic wave detector 50 to second wiring 71 also overlaps second wiring 71.

First insulation layer 31 is provided between first pillar portion 21 and second wiring 7 to electrically insulate first pillar portion 21 and second wiring 7. This configuration prevents DC current from flowing between first pillar portion 21 and second wiring 7 through first insulating layer 31. First intermediate layer 41 is provided between first insulation layer 31 and second wiring 7. Second insulation layer 32 is provided between second pillar portion 22 and first wiring 6 to electrically insulate second pillar portion 22 and first wiring 6. This configuration prevents DC current from flowing between second pillar portion 22 and first wiring 6 through second insulation layer 32. Second intermediate layer 42 is provided between second insulation layer 32 and first wiring 6. First intermediate layer 41 and second intermediate layer 42 are formed from a conductor but may also be formed from an insulator. First pillar portion 21, first insulation layer 31, and first intermediate layer 41 constitute first columnar body 51 that extends in the Z-direction from first wiring 6 to second wiring 7. First columnar body 51 supports first arm part 11 and in turn supports electromagnetic wave detector 5 via first arm part 11. First columnar body 51 also supports second wiring 7. Second pillar portion 22, second insulation layer 32, and second intermediate layer 42 constitute second columnar body 52 that extends in the Z-direction from first wiring 6 to second wiring 7. Second columnar body 52 supports second arm part 12 and in turn supports electromagnetic wave detector 5 via second arm part 12. Second columnar body 52 also supports second wiring 7. First pillar portion 21, first insulation layer 31, and first intermediate layer 41 are cylindrical or disc-shaped and concentric with each other but their shapes are not limited. Similarly, second pillar portion 22, second insulation layer 32, and second intermediate layer 42 are cylindrical or disc-shaped and concentric with each other but their shapes are not limited.

### Configuration of Second Wirings 7

The configuration of second wirings 7 is next described. In the following description, one of first wirings 6 will be referred to as first wiring 61, one of second wirings 7 will be referred to as second wiring 71, and one second wiring 7 adjacent to second wiring 71 in the +X-direction will be referred to as second wiring 72. Electromagnetic wave detector 50 is electrically connected to first wiring 61 via first pillar portion 21 and electrically connected to second wiring 71 via second pillar portion 22. Second wirings 7 have a greater thickness (the dimension in the Z-direction) and a greater width (the dimension in the X-direction of second wirings 7 and the dimension in the Y-direction of first wirings 6) than first wirings 6, but the shapes of first wirings 6 and second wirings 7 are not limited. The surfaces of second wirings 7 that face first wirings 6 are parallel to the X-direction and the Y-direction and are flat.

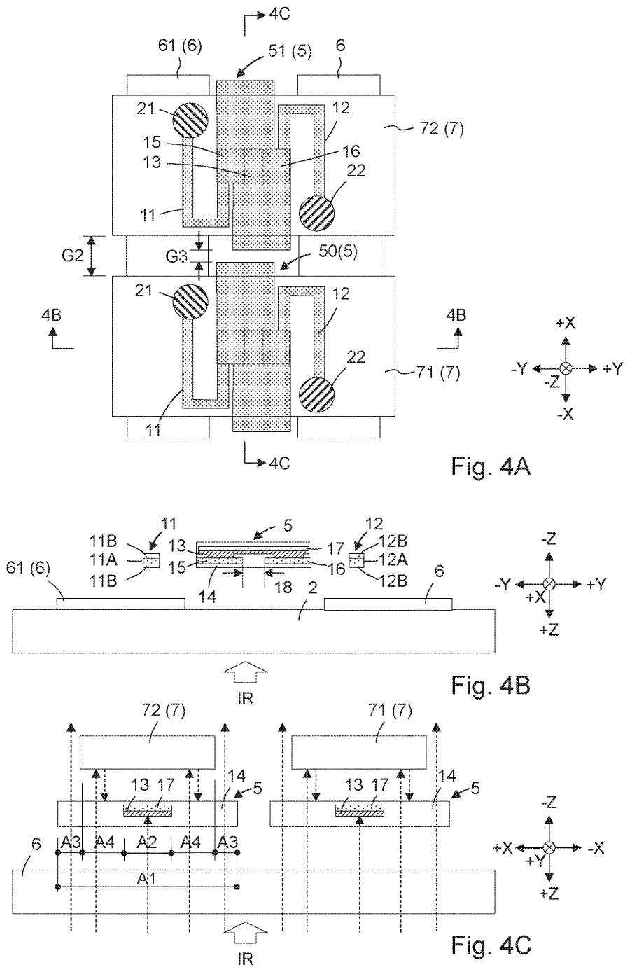

FIG. 4A is a partially enlarged plan view of an electromagnetic wave sensor of Comparative Example 1 viewed from the +Z-direction, FIG. 4B is a schematic cross-sectional view taken along line 4B−4B of FIG. 4A, and FIG. 4C is a schematic cross-sectional view taken along line 4C−4C of FIG. 4A. FIG. 4A shows electromagnetic wave detectors 5, first pillar portions 21, and second pillar portions 22 for convenience. The configuration and shape of electromagnetic wave detectors 5, first electrode layers 15, second electrode layers 16, and third electrode layers 17 are the same as in the first embodiment. In each electromagnetic wave detector, the entirety of first electrode layer 15, second electrode layer 16, and third electrode layer 17 overlap second wiring 71 (or second wiring 72) when viewed from the Z-direction. In electromagnetic wave detectors 5, the area in which at least one of first electrode layer 15, second electrode layer 16, and third electrode layer 17 is present will be referred to as electrode area A2. Since first electrode layer 15, second electrode layer 16, and third electrode layer 17 transmit virtually no electromagnetic waves, electrode area A2 is an area in which electromagnetic waves are for the most part not transmitted. Of the electromagnetic waves incident to electromagnetic wave detectors 5, the electromagnetic waves that are substantially transmitted through electromagnetic wave detectors 5 are limited to those that pass through areas of electromagnetic wave detectors 5 other than electrode areas A2.

Interspace G2 in the X-direction of second wirings 7 may be larger than interspace G3 in the X-direction of electromagnetic wave detectors 5 to prevent short circuits. In the first embodiment, interspace G2 of second wirings 7 in the X-direction is larger than interspace G3 of electromagnetic wave detectors 5 in the X-direction. As a result, the edges of electromagnetic wave detectors 5 in the +X-direction may protrude beyond second wirings 7 in the +X-direction and the edges in the −X-direction may protrude beyond second wirings 7 in the −X-direction as viewed from the Z-direction. Since the protruding portions do not overlap second wirings 7 in the Z-direction, electromagnetic waves transmitted through the protruding portions are not reflected by second wirings 7. In areas such as the protruding portions, electromagnetic waves are transmitted through electromagnetic wave detectors 5 but are not reflected and therefore not caused to again be incident to electromagnetic wave detectors 5. These areas will be referred to as nonreflective areas A3. Nonreflective areas A3 are areas in which electromagnetic waves are transmitted through electromagnetic wave detectors 5, but where, in the forward direction of the direction of incidence of electromagnetic waves (the −Z-direction), there are no second wirings 7 to reflect the electromagnetic waves toward electromagnetic wave detectors 5 and cause the electromagnetic waves to again be incident to electromagnetic wave detectors 5. Areas in which electromagnetic waves are substantially transmitted, are transmitted through electromagnetic wave detectors 5, and are then reflected by second wirings 7 to again be incident to electromagnetic wave detectors 5 will be referred to as reflective areas A4. In the present embodiment, reflective areas A4 are the areas of electromagnetic wave detectors 5 that overlap second wirings 7 when viewed from the Z-direction and where none of first electrode layer 15, second electrode layer 16, and third electrode layer 17 is present.

If the area of electromagnetic wave detector 50 (entire area A1) viewed from the Z-direction is S1, the area of electrode area A2 is S2, the area of nonreflective area A3 is S3, and the area of reflective area A4 is S4, then S4=S1−S2−S3. Thus, of the electromagnetic waves incident to electromagnetic wave detector 5 excluding the electromagnetic waves absorbed by electromagnetic wave detector 5, the ratio of the electromagnetic waves that are transmitted through electromagnetic wave detector 5, are reflected by second wiring 7, and are then again incident to electromagnetic wave detector 5 (electromagnetic wave re-incidence rate) can be considered to be (S1−S2−S3)/S1=S4/S1. In Comparative Example 1, interspace G3 of electromagnetic wave detectors 5 is smaller than interspace G2 of second wirings 7, and nonreflective areas A3 therefore tend to occur.

In the present embodiment, as shown in FIGS. 2A, 2B, and FIG. 3D, at least a part of first electrode layer 15, second electrode layer 16, and third electrode layer 17 overlaps interspace G2 in the X-direction between second wiring 71 and second wiring 72. In addition, electromagnetic wave detector 50 overlaps second wirings 71 and 72 and interspace G2 when viewed from the Z-direction. In other words, when viewed in the Z-direction, a part of electromagnetic wave detector 50 overlaps second wiring 71, a different part of electromagnetic wave detector 50 overlaps second wiring 72, and excluding the above part and the above different part, the remaining parts of electromagnetic wave detector 50 overlap neither second wiring 71 nor second wiring 72. In the present embodiment, the entire area of each of first electrode layer 15, second electrode layer 16, and third electrode layer 17 overlaps interspace G2 in the X-direction between second wiring 71 and second wiring 72 when viewed from the Z-direction, and second wirings 7 are not present in the forward direction of the electromagnetic waves (the −Z-direction) of first electrode layer 15, second electrode layer 16, and third electrode layer 17. In the present embodiment, in an area that overlaps interspace G2 of electromagnetic wave detectors 5 as viewed from the Z-direction, electrode area A2 is larger than areas in which electrode area A2 is not present. Although not shown in the drawings, when viewed from the Z-direction, a part of first electrode layer 15 may overlap interspace G2, a part of second electrode layer 16 may overlap interspace G2, or a part of third electrode layer 17 may overlap interspace G2. In addition, one end 5A of electromagnetic wave detector 5 in the +X-direction overlaps second wiring 72, and the other end 5B of electromagnetic wave detector 5 in the −X-direction overlaps second wiring 71 when viewed from the Z-direction. As a result, the above-mentioned protruding portions do not occur, and of the areas of overlap between interspace G2 and electromagnetic wave detector 5 when viewed from the Z-direction, nonreflective areas A3 are limited to areas other than electrode area A2. The area S2 of electrode area A2 is the same as in Comparative Example 1, but because at least a part of electrode area A2 overlaps interspace G2, the area S3 of nonreflective area A3 decreases and the area S4 of reflective area A4 increases compared to Comparative Example 1. Therefore, the re-incidence rate of the electromagnetic waves increases, and more reflected waves can be absorbed than in Comparative Example 1. In other words, the absorption efficiency of the electromagnetic waves absorbed by electromagnetic wave detectors 5 in electromagnetic wave sensor 100 can be increased.

Compared to Comparative Example 1, second wirings 7 in the present embodiment are shifted in the X-direction by half of the X-directional array pitch of electromagnetic wave detectors 5. In other words, center line C5 in the X-direction of electromagnetic wave detectors 5 is at a position equidistant from center lines C71 and C72 in the X-direction of second wirings 71 and 72 that are adjacent in the X-direction. Temperature detection film 13 that is provided with first electrode layer 15, second electrode layer 16, and third electrode layer 17 is positioned near the center of electromagnetic wave detector 5 in the X-direction. As a result, shifting center line C71 of second wiring 71 and center line C72 of second wiring 72 in the X-direction by half of the X-directional array pitch of electromagnetic wave detector 5 relative to center line C5 of electromagnetic wave detectors 5 enables an effective reduction of the area S3 of nonreflective area A3. However, the amount by which centerlines C71 and C72 of second wirings 71 and 72 are shifted with respect to centerline C5 of electromagnetic wave detectors 5 is not limited and can be adjusted to the extent that at least a part of first electrode layer 15, second electrode layer 16, and third electrode layer 17 overlaps interspace G2 as viewed from the Z-direction.

### Modification 1

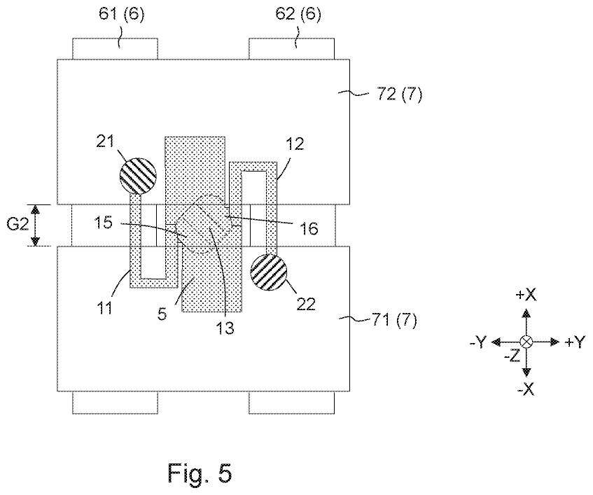

FIG. 5 shows a plan view of electromagnetic wave detector 5 of Modification 1. As shown in FIG. 5, the centerline (axis of symmetry) of temperature detection film 13 of electromagnetic wave detector 5 of Modification 1 is inclined with respect to the X-direction and the Y-direction when viewed from the Z-direction. In this configuration, since at least a part of first electrode layer 15, second electrode layer 16, and third electrode layer 17 overlaps interspace G2, the absorption efficiency of electromagnetic waves absorbed by electromagnetic wave detector 5 increases.

### Modification 2

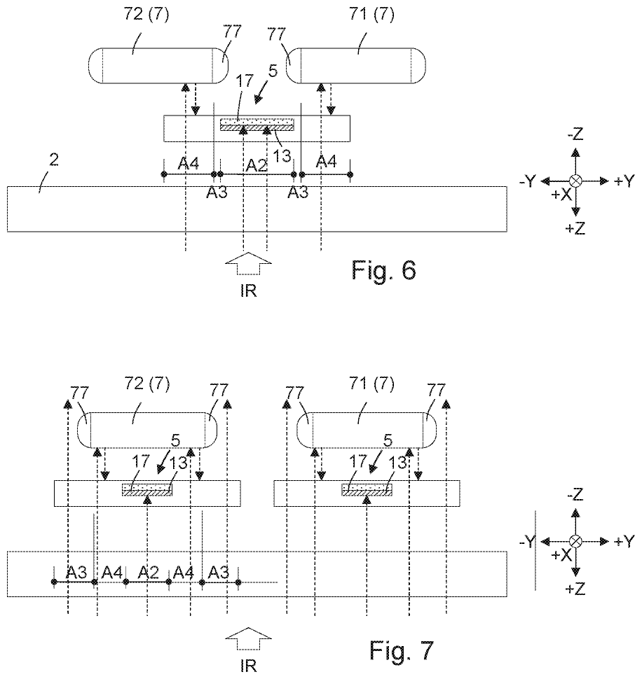

FIG. 6 is a schematic cross-sectional view of Modification 2 taken at the same cross-sectional position as in FIG. 3D, and FIG. 7 is a schematic cross-sectional view of Comparative Example 2 taken at the same cross-sectional position as in FIG. 3D. In Modification 2 and Comparative Example 2, the ends of second wirings 7 each have a rounded shape in the width direction (the X-direction). When rounded ends 77 overlap areas excluding electrode area A2 of electromagnetic wave detector 5 when viewed from the Z-direction, as in Comparative Example 2, nonreflective areas A3 increase compared to a case in which ends 77 are not rounded, and as a result, the electromagnetic wave absorption efficiency of Comparative Example 2 may be even lower than that of Comparative Example 1. In Modification 2, because ends 77 overlap at least a part of first electrode layer 15, second electrode layer 16, and third electrode layer 17, the absorption efficiency of electromagnetic waves absorbed by the electromagnetic wave detector can be increased as in the first embodiment.

### Second Embodiment

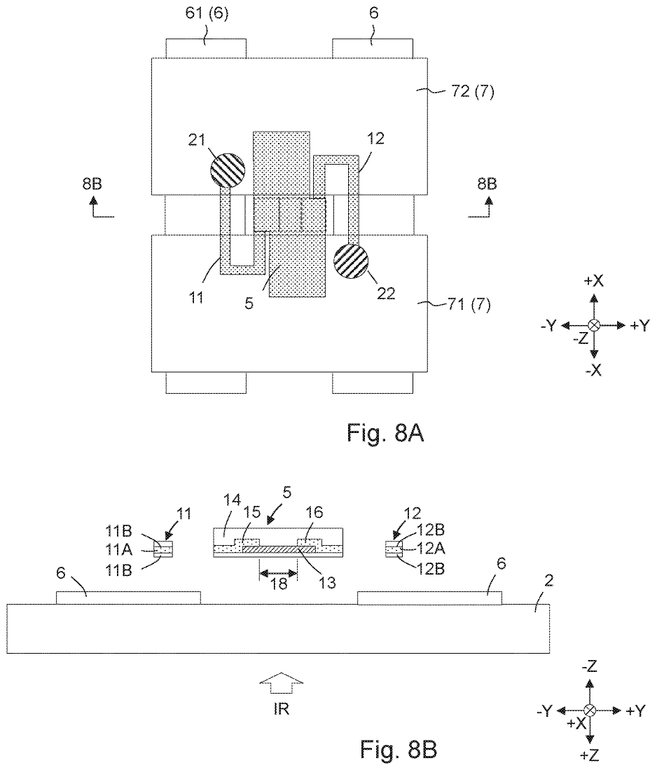

FIG. 8A is a partial plan view of electromagnetic wave sensor 100 of the second embodiment as viewed in the +Z-direction, and FIG. 8B is a schematic cross-sectional view taken along line 8B−8B of FIG. 8A. Description of the second embodiment focuses on points that differ from the first embodiment. Configurations and effects that are the same as those of the first embodiment are omitted from the explanation. In the present embodiment, third electrode layer 17 shown in the first embodiment is omitted. Electric current flows in the XY plane of temperature detection film 13. When viewed from the Z-direction, only temperature detection film 13 and electromagnetic wave absorber 14 are present in gap 18 between first electrode layer 15 and second electrode layer 16. A part of the electromagnetic waves incident to gap 18 is transmitted through electromagnetic wave detector 5. Since second wiring 7 is not present in the path of incidence of the electromagnetic waves (the −Z-direction), gap 18 becomes nonreflective area A3. As in the first embodiment, the absorption efficiency of electromagnetic waves absorbed by electromagnetic wave detector 5 in the present embodiment can be improved.

Although certain embodiments of the present disclosure have been illustrated and described in detail, it will be understood that various changes and modifications can be made therein without departing from the spirit or scope of the appended claims.

### LIST OF REFERENCE NUMERALS

5 electromagnetic wave detector
6, 61 first wirings
7, 71, 72 second wirings
13 temperature detection film
14 electromagnetic wave absorber
15, 16, 17 electrode
21 first pillar portion
22 second pillar portion
100 electromagnetic wave sensor
G2 interspace
X first direction
Y second direction
Z third direction

1. An electromagnetic wave sensor, comprising:
a first wiring that extends in a first direction;
two second wirings that are separated by an interspace in the first direction and that extend in a second direction that is different from the first direction; and
a bolometer that includes electrodes, wherein
the first wiring is positioned on a side where electromagnetic waves to be measured are incident, relative to the bolometer, and position of the bolometer in a third direction that is orthogonal to the first direction and the second direction is between position of the first wiring in the third direction and position of the second wirings in the third direction,
when viewed from the third direction, at least a part of the electrodes overlaps the interspace, and
when viewed from the third direction, the bolometer overlaps the two second wirings.

2. The electromagnetic wave sensor according to claim 1, wherein, when viewed from the third direction, an entire area of the electrodes overlaps the interspace.

3. The electromagnetic wave sensor according to claim 1, wherein, when viewed from the third direction, one end of the bolometer in the first direction overlaps one of the two second wirings, and another end of the bolometer in the first direction overlaps a remaining one of the two second wirings.

4. The electromagnetic wave sensor according to claim 1, wherein
the bolometer includes a first pillar portion that is electrically connected to the first wiring and a second pillar portion that is electrically connected to one of the two second wirings, and
when viewed from the third direction, the first pillar portion overlaps a remaining one of the two second wirings.

5. The electromagnetic wave sensor according to claim 1, wherein ends of the two second wirings are rounded, and, when viewed from the third direction, the ends overlap at least a part of the electrodes.

6. The electromagnetic wave sensor according to claim 1, wherein the electrodes include a first electrode that is electrically connected to the first wiring, a second electrode that is electrically connected to one of the two second wirings, and a third electrode that overlaps the first and second electrodes when viewed from the third direction.

7. An electromagnetic wave sensor, comprising:
a first wiring that extends in a first direction;
two second wirings that are separated by an interspace in the first direction and that extend in a second direction that is different from the first direction; and
an electromagnetic wave detector that includes an electromagnetic wave absorber and electrodes, wherein
the first wiring is positioned on a side where electromagnetic waves to be measured are incident, relative to the electromagnetic wave detector, and position of the electromagnetic wave detector in a third direction that is orthogonal to the first direction and the second direction is between position of the first wiring in the third direction and position of the second wirings in the third direction,
when viewed from the third direction, at least a part of the electrodes overlaps the interspace, and
when viewed from the third direction, the electromagnetic wave detector overlaps the two second wirings.
